(19) United States
(12) Patent Application Publication
(10) Pub. No.: US 2015/0371865 A1
(43) Pub. Date: Dec. 24, 2015

(54) HIGH SELECTIVITY GAS PHASE SILICON NITRIDE REMOVAL

(71) Applicant: Applied Materials, Inc., Santa Clara, CA (US)

(72) Inventors: Zhijun Chen, Milpitas, CA (US); Nitin K. Ingle, San Jose, CA (US); Anchuan Wang, San Jose, CA (US)

(21) Appl. No.: 14/308,978

(22) Filed: Jun. 19, 2014

(51) Int. Cl. H01L 21/311; C09K 13/08

(52) U.S. Cl. CPC H01L 21/31116; C09K 13/08

(57) ABSTRACT

A method of etching silicon nitride on patterned heterogeneous structures is described and includes a gas phase etch using partial remote plasma excitation. The remote plasma excites a fluorine-containing precursor and the plasma effluents created are flowed into a substrate processing region. A hydrogen-containing precursor, e.g. water, is concurrently flowed into the substrate processing region without plasma excitation. The plasma effluents are combined with the unexcited hydrogen-containing precursor in the substrate processing region where the combination reacts with the silicon nitride. The plasmas effluents react with the patterned heterogeneous structures to selectively remove silicon nitride while retaining silicon, such as polysilicon.

### FIELD

Embodiments of the invention relate to selectively removing silicon nitride.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning layers or thinning lateral dimensions of features already present on the surface. Often it is desirable to have an etch process which removes one material faster than another helping e.g. a pattern transfer process proceed. Such an etch process is said to be selective to the first material. As a result of the diversity of materials, circuits and processes, etch processes have been developed with a selectivity towards a variety of materials. However, there are few options for selectively removing silicon nitride faster than silicon.

Dry etch processes are often desirable for selectively removing material from semiconductor substrates. The desirability stems from the ability to gently remove material from miniature structures with minimal physical disturbance. Dry etch processes also allow the etch rate to be abruptly stopped by removing the gas phase reagents. Some dry-etch processes involve the exposure of a substrate to remote plasma by-products formed from one or more precursors. For example, remote plasma excitation of ammonia and nitrogen trifluoride enables silicon oxide to be selectively removed from a patterned substrate when the plasma effluents are flowed into the substrate processing region. Remote plasma etch processes have also been developed to remove silicon nitride, however, the silicon nitride selectivity of these etch processes (relative to silicon) can still benefit from further improvements.

Methods are needed to improve silicon nitride etch selectivity relative to silicon for dry etch processes.

### SUMMARY

A method of etching silicon nitride on patterned heterogeneous structures is described and includes a gas phase etch using partial remote plasma excitation. The remote plasma excites a fluorine-containing precursor and the plasma effluents created are flowed into a substrate processing region. A hydrogen-containing precursor, e.g. water, is concurrently flowed into the substrate processing region without plasma excitation. The plasma effluents are combined with the unexcited hydrogen-containing precursor in the substrate processing region where the combination reacts with the silicon nitride. The plasmas effluents react with the patterned heterogeneous structures to selectively remove silicon nitride while retaining silicon, such as polysilicon.

Embodiments of the invention include methods of etching a patterned substrate. The methods include transferring the patterned substrate into a substrate processing region of a substrate processing chamber. The patterned substrate has an exposed portion of silicon nitride and an exposed portion of silicon. The methods further include flowing a fluorine-containing precursor into a remote plasma region fluidly coupled to the substrate processing region while forming a remote plasma in the remote plasma region to produce plasma effluents. The methods further include flowing a hydrogen-containing precursor into the substrate processing region without first passing the hydrogen-containing precursor through the remote plasma region. The methods further include combining the hydrogen-containing precursor and the plasma effluents in the substrate processing region. The methods further include etching the exposed portion of silicon nitride.

Embodiments of the invention include methods of etching a patterned substrate. The methods include transferring the patterned substrate into a substrate processing region of a substrate processing chamber. The patterned substrate has exposed silicon nitride and exposed silicon. The methods further include flowing a fluorine-containing precursor into a remote plasma region fluidly coupled to the substrate processing region while forming a remote plasma in the remote plasma region to produce plasma effluents. The methods further include flowing water vapor into the substrate processing region without first passing the water vapor through any remote plasma. The methods further include etching the exposed silicon nitride.

Embodiments of the invention include methods of etching a patterned substrate. The methods include transferring the patterned substrate into a substrate processing region of a substrate processing chamber. The patterned substrate has exposed silicon nitride and exposed silicon. The methods further include flowing nitrogen trifluoride into a remote plasma region fluidly coupled to the substrate processing region while forming a remote plasma in the remote plasma region to produce plasma effluents. The methods further include flowing water vapor into the substrate processing region without first passing the water vapor through the remote plasma region. The methods further include etching the exposed silicon nitride, wherein a temperature of the patterned substrate is between about 40° C. and about 80° C. during the operation of etching the exposed silicon nitride. The methods further include removing the patterned substrate from the substrate processing region.

Additional embodiments and features are set forth in part in the description that follows, and in part will become apparent to those skilled in the art upon examination of the specification or may be learned by the practice of the disclosed embodiments. The features and advantages of the disclosed embodiments may be realized and attained by means of the instrumentalities, combinations, and methods described in the specification.

### DESCRIPTION OF THE DRAWINGS

A further understanding of the nature and advantages of the disclosed technology may be realized by reference to the remaining portions of the specification and the drawings.

FIG. 1 shows a method of selectively etching silicon nitride according to embodiments of the invention.

FIG. 2 shows a method of selectively etching silicon nitride according to embodiments of the invention.

FIG. 3 is a chart of etch rates for etch processes according to embodiments of the invention.

FIG. 4 shows a top plan view of one embodiment of an exemplary processing tool according to embodiments of the invention.

FIGS. 5A and 5B show cross-sectional views of an exemplary processing chamber according to embodiments of the invention.

FIG. 6 shows a schematic view of an exemplary showerhead configuration according to embodiments of the invention.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

A method of etching silicon nitride on patterned heterogeneous structures is described and includes a gas phase etch using partial remote plasma excitation. The remote plasma excites a fluorine-containing precursor and the plasma effluents created are flowed into a substrate processing region. A hydrogen-containing precursor, e.g. water, is concurrently flowed into the substrate processing region without plasma excitation. The plasma effluents are combined with the unexcited hydrogen-containing precursor in the substrate processing region where the combination reacts with the silicon nitride. The plasmas effluents react with the patterned heterogeneous structures to selectively remove silicon nitride while retaining silicon, such as polysilicon.

Selective remote gas phase etch processes have used aggressive oxidizing precursors in combination with remotely excited fluorine-containing precursor to achieve etch selectivity of silicon nitride relative to silicon. Aggressive oxidizing precursors were used to oxidize a thin layer of the silicon to prevent further etching. The methods presented herein remove the oxidation requirement which further enhances the effective selectivity. These advantages may become increasingly desirable for decreased feature sizes.

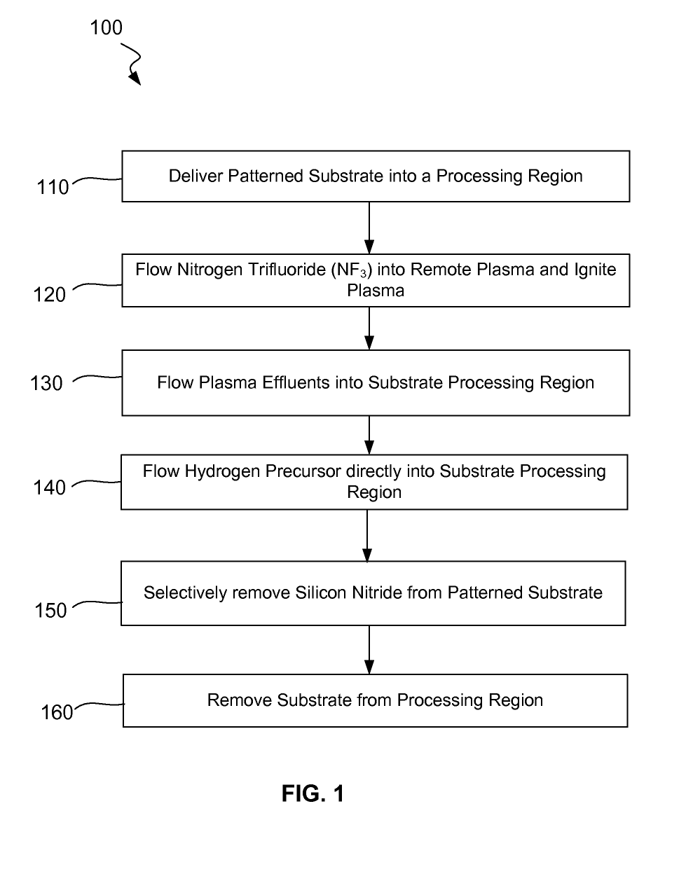

In order to better understand and appreciate the invention, reference is now made to FIG. 1 which is a flow chart of a silicon nitride selective etch process 100 according to embodiments. Prior to the first operation, a structure is formed in a patterned substrate. The structure possesses exposed portions of silicon nitride and silicon. The substrate is then delivered into a substrate processing region in operation 110.

A flow of nitrogen trifluoride is initiated into a remote plasma region (fluidly coupled but separate from the processing region) in operation 120. Other sources of fluorine may be used to augment or replace the nitrogen trifluoride. In general, a fluorine-containing precursor is flowed into the remote plasma region and the fluorine-containing precursor comprises at least one precursor selected from the group consisting of atomic fluorine, diatomic fluorine, nitrogen trifluoride, carbon tetrafluoride, hydrogen fluoride and xenon difluoride. The separate plasma region may be referred to as a remote plasma region herein and may be within a distinct module from the processing chamber or a compartment within the processing chamber. A plasma is ignited and the plasma effluents formed in the remote plasma region are then flowed into the substrate processing region (operation 130). Water vapor (also referred to herein as moisture or H₂O) is simultaneously flowed into the substrate processing region (operation 140) to react with the plasma effluents. The water vapor is not passed through the remote plasma region and therefore is only excited by interaction with the plasma effluents. The water vapor is not passed through any remote plasma region before entering the substrate processing region according to embodiments.

The patterned substrate is selectively etched (operation 150) such that the exposed silicon nitride is selectively removed at a higher rate than the exposed silicon. Rather than oxidizing the exposed silicon to prevent etching, the precursor combinations described herein have been found to produce reactants which etch only the silicon nitride, in embodiments, so no silicon is consumed to produce a protective silicon oxide layer. Silicon oxide is also not etched using these chemistries and so portions of exposed silicon oxide are also present on the patterned substrate according to embodiments. Process effluents and unreacted reactants are removed from the substrate processing region and then the substrate is removed from the processing region (operation 160).

The etch processes introduced herein have been found to provide silicon nitride etch selectivity not only to high density silicon oxide films but also to low density silicon oxide films. The broad silicon nitride selectivity enables these gas phase etches to be used in a broader range of process sequences. Exemplary deposition techniques which result in low density silicon oxide include chemical vapor deposition using dichlorosilane as a deposition precursor, spin-on glass (SOG) or plasma-enhanced chemical vapor deposition. High density silicon oxide may be deposited as thermal oxide (exposing silicon to, e.g., 0₂ at high temperature), disilane precursor furnace oxidation or high-density plasma chemical vapor deposition according to embodiments.

Gas phase etches involving only a fluorine-containing precursor (either remote or local but without the unexcited hydrogen-containing precursor) do not possess the selectivity needed to remove silicon nitride while leaving exposed silicon portions undisturbed. The flow of H₂O (or another hydrogen-containing precursor as described in the next example) directly into the substrate processing region combines with plasma effluents. The plasma effluents comprise radical-fluorine formed from the flow of the fluorine-containing precursor into the remote plasma region. The flow of the hydrogen-containing precursor into the substrate processing region enables the radical-fluorine to remove the silicon nitride while limiting the removal rate of the exposed silicon. The combination of the plasma effluents and the hydrogen-containing precursor may be forming hydrogen fluoride and/or related reactants. These reactants are suited to removing silicon nitride but do not remove silicon oxide and, more remarkably, do not remove exposed silicon either. Exposed silicon oxide is optionally present on the patterned substrate.

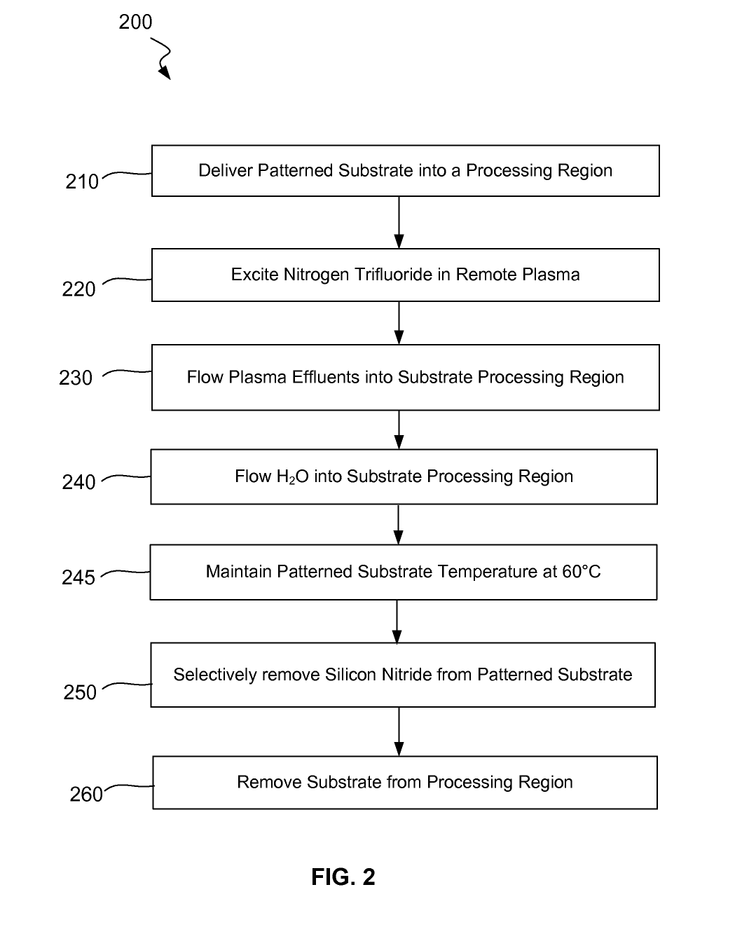

Using the gas phase dry etch processes described herein, the etch selectivities have been increased compared to older techniques which rely on the formation of a protective thin silicon oxide layer over silicon portions. Selectivity will be defined herein by determining how far a silicon interface has moved so the protective silicon oxide layer is considered “etched” silicon. Including the hydrogen-containing precursor without plasma excitation, as described herein, may not significantly affect the etch rate of the silicon nitride but decreases the etch rate of silicon, leading to a high selectivity. The etch process parameters described herein apply to all embodiments disclosed herein, include the embodiments described in FIG. 2 below. The selectivity of etch process 100 (exposed silicon nitride: exposed silicon) is greater than or about 50:1, greater than or about 75:1 or greater than or about 100:1 in embodiments. No measurable amount of silicon was etched using etch process 100 according to embodiments. The exposed portion of silicon has an exposed surface having no native oxide or silicon oxide on the exposed surface in disclosed embodiments. The fluorine-containing precursor and/or the hydrogen-containing precursor may further include one or more relatively inert gases (e.g. He, N₂, Ar). Flow rates and ratios of the different gases may be used to control etch rates and etch selectivity. In an embodiment, the fluorine-containing gas includes NF₃ at a flow rate of between about 5 sccm (standard cubic centimeters per minute) and 300 sccm, H₂O at a flow rate of between about 25 sccm and 700 sccm (standard liters per minute) and He at a flow rate of between about 0 sccm and 3000 sccm. Argon may be included, especially when initially striking a plasma, to facilitate the initiation of the plasma. One of ordinary skill in the art would recognize that other gases and/or flows may be used depending on a number of factors including processing chamber configuration, substrate size, geometry and layout of features being etched.

Reference is now made to FIG. 2 which is a flow chart of a silicon nitride selective etch process 200 according to embodiments. Prior to the first operation, a structure is formed in a patterned substrate. The structure possesses exposed portions of silicon nitride and silicon (e.g. single crystal silicon or polysilicon). The patterned substrate is then delivered into a substrate processing region in operation 210.

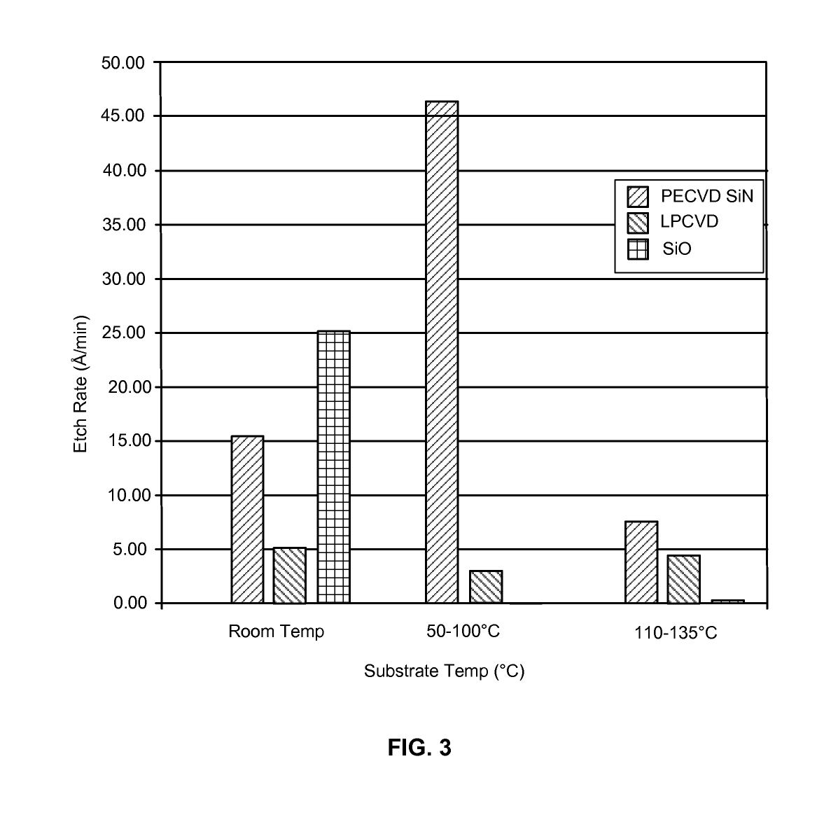

Nitrogen trifluoride is flowed into a remote plasma region and excited in a plasma (operation 220). The remote plasma region may be outside or inside the substrate processing chamber in embodiments. Plasma effluents are formed from the nitrogen trifluoride in the plasma and flowed from the remote plasma region into the substrate processing region in operation 230. A hydrogen-containing precursor is concurrently and directly flowed into the substrate processing region (operation 240) without first passing through any plasma. During the reaction, the patterned substrate is maintained at a temperature of 60° C. (operation 245). The temperature is generally higher than other gas-phase ion-suppressed processes because lower temperatures (e.g. <40° C.) and higher substrate temperatures (e.g. >80° C.) were found to reduce the silicon nitride etch rate. FIG. 3 is a chart of etch rates for etch processes according to embodiments of the invention. A variety of densities resulting from various silicon nitride deposition techniques (e.g. PECVD and or LPCVD SiN all possess significant etch rates across substrate temperatures. Silicon oxide, on the other hand, has a significant etch rate for room temperature substrates (the typical operating regime for these processes) but the etch rate becomes negligible for moderately high temperatures (50-100° C.) and even high temperatures (110-135° C.) according to embodiments.

The hydrogen-containing precursor may be one of hydrogen (H₂), water (H₂O) or an alcohol (containing an —OH group). The alcohol may be, for example, methanol, ethanol or isopropyl alcohol. The fluorine-containing precursor may be the same embodiments described earlier. The hydrogen-containing precursor is mixed with the plasma effluents in the substrate processing region. The hydrogen-containing precursor and the plasma effluents do not encounter one another prior to entering the substrate processing region according to embodiments. The patterned substrate is selectively etched (operation 250) such that the exposed silicon nitride is selectively removed at a higher rate than the exposed silicon. Portions of exposed silicon oxide may also be present on the patterned substrate and may also be essentially unetched during operation 250. The reactive chemical species are removed from the substrate processing region and then the patterned substrate is removed from the processing region (operation 260).

In all processes described herein the remote plasma region may be devoid of hydrogen, in embodiments, during the excitation of the remote plasma. For example, the remote plasma region may be devoid of ammonia during excitation of the remote plasma. A hydrogen source (e.g. ammonia) may interact with the fluorine-containing precursor in the plasma to form precursors which remove silicon oxide by forming solid residue by-products on the oxide surface. This reaction reduces the selectivity of the exposed silicon nitride portions as compared with exposed silicon oxide portions. An oxygen-containing precursor may be flowed into the remote plasma region, according to embodiments, to be excited along with the fluorine-containing precursor. The oxygen-containing precursor may include one or more of oxygen, ozone and nitrous oxide. Introducing oxygen through the remote plasma (in combination with the hydrogen-containing precursor through the unexcited route) has been found to be an effective alternative process for selectively etching silicon nitride. The following embodiments have been found to produce desired results. During the ignition of the remote plasma, the remote plasma region may be oxygen-free while supplying an oxygen-containing hydrogen-containing precursor (e.g. H₂O) directly into the substrate processing region. Alternatively, the remote plasma region may contain oxygen (e.g. O₂) while supplying an oxygen-free hydrogen-containing precursor (e.g. H₂) directly into the substrate processing region. Lastly, the remote plasma region may contain oxygen while supplying an oxygen-containing hydrogen-containing precursor directly into the substrate processing region.

The method also includes applying power to the fluorine-containing precursor in the remote plasma region to generate the plasma effluents. As would be appreciated by one of ordinary skill in the art, the plasma may include a number of charged and neutral species including radicals and ions. The plasma may be generated using known techniques (e.g., RF, capacitively coupled, inductively coupled). In embodiments, the remote plasma power is applied to the remote plasma region at a level between 5 W and 5 kW or between 25 W and 500 W. The remote plasma power may be applied using inductive coils, in embodiments, in which case the remote plasma will be referred to as an inductively-coupled plasma (ICP). The remote plasma power may be a capacitively-coupled plasma in embodiments. The pressure in the remote plasma region and the substrate processing region may be between about 0.01 Torr and about 30 Torr, between about 0.1 Torr and about 15 Torr, or between about 1 Torr and about 5 Torr in embodiments. The remote plasma region is disposed remote from the substrate processing region. The remote plasma region is fluidly coupled to the substrate processing region. The temperature of the patterned substrate during the etch processes described herein may be between about 0° C. and about 140° C. in disclosed embodiments. The temperature of the patterned substrate may be between about 20° C. and about 130° C., may be between about 25° C. and about 90° C. or between about 40° C. and about 80° C. during the etching operation according to embodiments.

In embodiments, an ion suppressor as described in the exemplary equipment section may be used to provide radical and/or neutral species for selectively etching silicon nitride. The ion suppressor may also be referred to as an ion suppression element. In embodiments, for example, the ion suppressor is used to filter etching plasma effluents (including radical-fluorine) to selectively etch silicon nitride. The ion suppressor may be included in each exemplary process described herein. Using the plasma effluents, an etch rate selectivity of silicon nitride relative to silicon and silicon oxide may be achieved.

The ion suppressor may be used to provide a reactive gas having a higher concentration of radicals than ions. Plasma effluents pass through the ion suppressor disposed between the remote plasma region and the substrate processing region. The ion suppressor functions to dramatically reduce or substantially eliminate ionically charged species traveling from the plasma generation region to the substrate. The electron temperature may be measured using a Langmuir probe in the substrate processing region during excitation of a plasma in the remote plasma region on the other side of the ion suppressor. In embodiments, the electron temperature may be less than 0.5 eV, less than 0.45 eV, less than 0.4 eV, or less than 0.35 eV. These extremely low values for the electron temperature are enabled by the presence of the showerhead and/or the ion suppressor positioned between the substrate processing region and the remote plasma region. Uncharged neutral and radical species may pass through the openings in the ion suppressor to react at the substrate. Because most of the charged particles of a plasma are filtered or removed by the ion suppressor, the substrate is not necessarily biased during the etch process. Such a process using radicals and other neutral species can reduce plasma damage compared to conventional plasma etch processes that include sputtering and bombardment. The ion suppressor helps control the concentration of ionic species in the reaction region at a level that assists the process. Embodiments of the present invention are also advantageous over conventional wet etch processes where surface tension of liquids can cause bending and peeling of small features.

Alternatively, the substrate processing region may be described herein as “plasma-free” during the etch processes described herein. “Plasma-free” does not necessarily mean the region is devoid of plasma. Ionized species and free electrons created within the plasma region may travel through pores (apertures) in the partition (showerhead) at exceedingly small concentrations. The borders of the plasma in the chamber plasma region are hard to define and may encroach upon the substrate processing region through the apertures in the showerhead. Furthermore, a low intensity plasma may be created in the substrate processing region without eliminating desirable features of the etch processes described herein. All causes for a plasma having much lower intensity ion density than the chamber plasma region during the creation of the excited plasma effluents do not deviate from the scope of “plasma-free” as used herein.

Additional process parameters are disclosed in the course of describing an exemplary processing chamber and system.

### Exemplary Processing System

Processing chambers that may implement embodiments of the present invention may be included within processing platforms such as the FRONTIER system, available from Applied Materials, Inc. of Santa Clara, Calif.

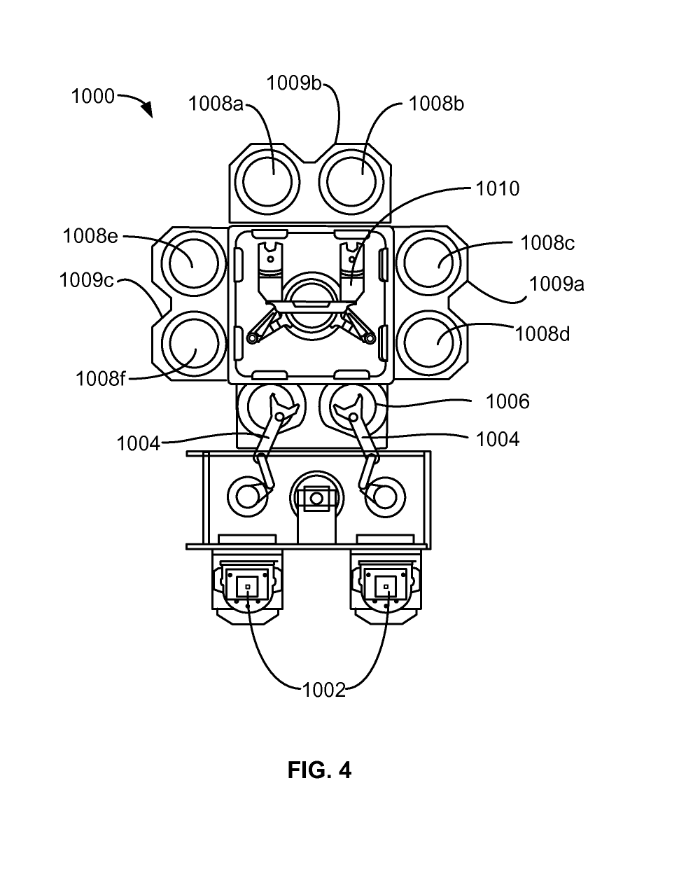

FIG. 4 shows a top plan view of one embodiment of a processing tool 1000 of deposition, etching, baking, and curing chambers according to disclosed embodiments. In the figure, a pair of front opening unified pods (FOUPs) 1002 supply substrates of a variety of sizes that are received by robotic arms 1004 and placed into a low pressure holding area 1006 before being placed into one of the substrate processing chambers 1008a-f, positioned in tandem sections 1009a-c. A second robotic arm 1010 may be used to transport the substrate wafers from the holding area 106 to the substrate processing chambers 1008a-f and back. Each substrate processing chamber 1008a-f, can be outfitted to perform a number of substrate processing operations including the dry etch processes described herein in addition to cyclical layer deposition (CLD), atomic layer deposition (ALD), chemical vapor deposition (CVD), physical vapor deposition (PVD), etch, pre-clean, degas, orientation, and other substrate processes.

The substrate processing chambers 1008a-f may include one or more system components for depositing, annealing, curing and/or etching a film on the substrate wafer. In one configuration, two pairs of the processing chamber, e.g., 1008c-d and 1008e-f, may be used to deposit material on the substrate, and the third pair of processing chambers, e.g., 1008a-b, may be used to etch the deposited film. In another configuration, all three pairs of chambers, e.g., 1008a-f, may be configured to etch a film on the substrate. Any one or more of the processes described may be carried out in chamber(s) separated from the fabrication system shown in disclosed embodiments. Films may be dielectric, protective, or other material. It will be appreciated that additional configurations of deposition, etching, annealing, and curing chambers for films are contemplated by system 1000.

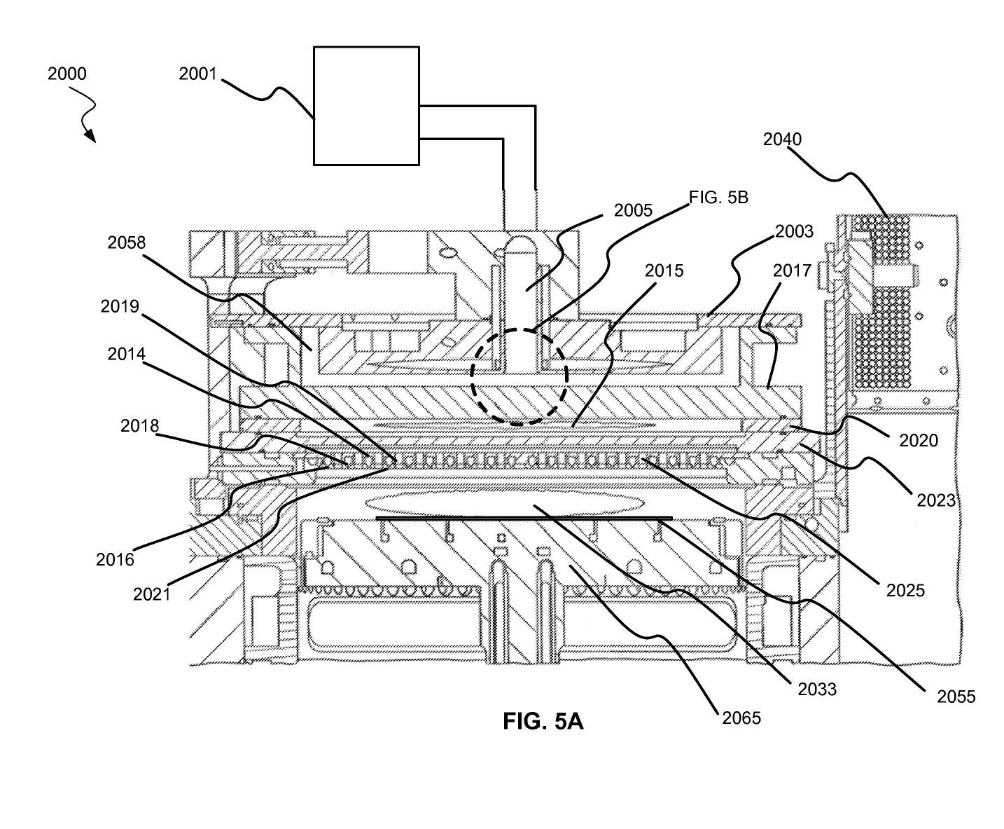

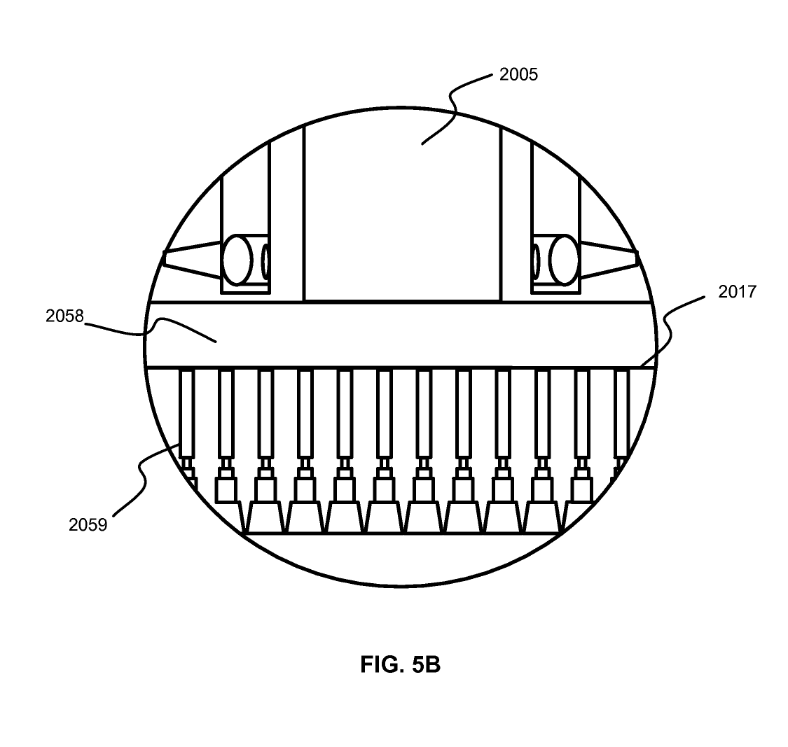

FIG. 5A shows a cross-sectional view of an exemplary process chamber section 2000 with partitioned plasma generation regions within the processing chamber. During film etching, e.g., silicon, polysilicon, silicon oxide, silicon nitride, silicon oxynitride, silicon oxycarbide, carbon-containing material, etc., a process gas may be flowed into the first plasma region 2015 through a gas inlet assembly 2005. A remote plasma system (RPS) unit 2001 may be included in the system, and may process a gas which then may travel through gas inlet assembly 2005. The inlet assembly 2005 may include two or more distinct gas supply channels where the second channel (not shown) may bypass the RPS unit 2001. Accordingly, in disclosed embodiments the precursor gases may be delivered to the processing chamber in an unexcited state. In another example, the first channel provided through the RPS may be used for the process gas and the second channel bypassing the RPS may be used for a treatment gas in disclosed embodiments. The process gases may be excited within the RPS unit 2001 prior to entering the first plasma region 2015. Accordingly, a fluorine-containing precursor, for example, may pass through RPS 2001 or bypass the RPS unit in disclosed embodiments. Various other examples encompassed by this arrangement will be similarly understood.

A cooling plate 2003, faceplate 2017, ion suppressor 2023, showerhead 2025, and a substrate support 2065, having a substrate 2055 disposed thereon, are shown and may each be included according to disclosed embodiments. The pedestal 2065 may have a heat exchange channel through which a heat exchange fluid flows to control the temperature of the substrate. This configuration may allow the substrate 2055 temperature to be cooled or heated to maintain relatively low temperatures, such as between about −20° C. to about 200° C., or there between. The heat exchange fluid may comprise ethylene glycol and/or water. The wafer support platter of the pedestal 2065, which may comprise aluminum, ceramic, or a combination thereof, may also be resistively heated in order to achieve relatively high temperatures, such as from up to or about 100° C. to above or about 1100° C., using an embedded resistive heater element. The heating element may be formed within the pedestal as one or more loops, and an outer portion of the heater element may run adjacent to a perimeter of the support platter, while an inner portion runs on the path of a concentric circle having a smaller radius. The wiring to the heater element may pass through the stem of the pedestal 2065, which may be further configured to rotate.

The faceplate 2017 may be pyramidal, conical, or of another similar structure with a narrow top portion expanding to a wide bottom portion. The faceplate 2017 may additionally be flat as shown and include a plurality of through-channels used to distribute process gases. Plasma generating gases and/or plasma excited species, depending on use of the RPS 2001, may pass through a plurality of holes in faceplate 2017 for a more uniform delivery into the first plasma region 2015.

Exemplary configurations may include having the gas inlet assembly 2005 open into a gas supply region 2058 partitioned from the first plasma region 2015 by faceplate 2017 so that the gases/species flow through the holes in the faceplate 2017 into the first plasma region 2015. Structural and operational features may be selected to prevent significant backflow of plasma from the first plasma region 2015 back into the supply region 2058, gas inlet assembly 2005, and fluid supply system (not shown). The structural features may include the selection of dimensions and cross-sectional geometries of the apertures in faceplate 2017 to deactivate back-streaming plasma. The operational features may include maintaining a pressure difference between the gas supply region 2058 and first plasma region 2015 that maintains a unidirectional flow of plasma through the showerhead 2025. The faceplate 2017, or a conductive top portion of the chamber, and showerhead 2025 are shown with an insulating ring 2020 located between the features, which allows an AC potential to be applied to the faceplate 2017 relative to showerhead 2025 and/or ion suppressor 2023. The insulating ring 2020 may be positioned between the faceplate 2017 and the showerhead 2025 and/or ion suppressor 2023 enabling a capacitively coupled plasma (CCP) to be formed in the first plasma region. A baffle (not shown) may additionally be located in the first plasma region 2015, or otherwise coupled with gas inlet assembly 2005, to affect the flow of fluid into the region through gas inlet assembly 2005.

The ion suppressor 2023 may comprise a plate or other geometry that defines a plurality of apertures throughout the structure that are configured to suppress the migration of charged species (e.g., ions) out of the plasma excitation region 2015 while allowing uncharged neutral or radical species to pass through the ion suppressor 2023 into an activated gas delivery region between the suppressor and the showerhead. In disclosed embodiments, the ion suppressor 2023 may comprise a perforated plate with a variety of aperture configurations. These uncharged species may include highly reactive species that are transported with less reactive carrier gas through the apertures. As noted above, the migration of ionic species through the holes may be reduced, and in some instances completely suppressed. Controlling the amount of ionic species passing through the ion suppressor 2023 may provide increased control over the gas mixture brought into contact with the underlying wafer substrate, which in turn may increase control of the deposition and/or etch characteristics of the gas mixture. For example, adjustments in the ion concentration of the gas mixture can significantly alter its etch selectivity. In alternative embodiments in which deposition is performed, it can also shift the balance of conformal-to-flowable style depositions for dielectric materials, carbon-containing materials, and other materials.

The plurality of holes in the ion suppressor 2023 may be configured to control the passage of the activated gas, i.e., the ionic, radical, and/or neutral species, through the ion suppressor 2023. For example, the aspect ratio of the holes, or the hole diameter to length, and/or the geometry of the holes may be controlled so that the flow of ionically-charged species in the activated gas passing through the ion suppressor 2023 is reduced. The holes in the ion suppressor 2023 may include a tapered portion that faces the plasma excitation region 2015, and a cylindrical portion that faces the showerhead 2025. The cylindrical portion may be shaped and dimensioned to control the flow of ionic species passing to the showerhead 2025. An adjustable electrical bias may also be applied to the ion suppressor 2023 as an additional means to control the flow of ionic species through the suppressor.

The ion suppression element 2023 may function to reduce or eliminate the amount of ionically-charged species traveling from the plasma generation region to the substrate. Uncharged neutral and radical species may still pass through the openings in the ion suppressor to react with the substrate. Showerhead 2025 in combination with ion suppressor 2023 may allow a plasma present in chamber plasma region 2015 to avoid directly exciting gases in substrate processing region 2033, while still allowing excited species to travel from chamber plasma region 2015 into substrate processing region 2033. In this way, the chamber may be configured to prevent the plasma from contacting a substrate 2055 being etched. This may advantageously protect a variety of intricate structures and films patterned on the substrate, which may be damaged, dislocated, or otherwise warped if directly contacted by a generated plasma. Additionally, when plasma is allowed to contact the underlying material exposed by trenches, such as the etch stop, the rate at which the underlying material etches may increase.

The processing system may further include a power supply 2040 electrically coupled with the processing chamber to provide electric power to the faceplate 2017, ion suppressor 2023, showerhead 2025, and/or pedestal 2065 to generate a plasma in the first plasma region 2015 or processing region 2033. The power supply may be configured to deliver an adjustable amount of power to the chamber depending on the process performed. Such a configuration may allow for a tunable plasma to be used in the processes being performed. Unlike a remote plasma unit, which is often presented with on or off functionality, a tunable plasma may be configured to deliver a specific amount of power to the plasma region 2015. This in turn may allow development of particular plasma characteristics such that precursors may be dissociated in specific ways to enhance the etching profiles produced by these precursors.

A plasma may be ignited either in chamber plasma region 2015 above showerhead 2025 or substrate processing region 2033 below showerhead 2025. A plasma may be present in chamber plasma region 2015 to produce radical-fluorine precursors from an inflow of a fluorine-containing precursor. An AC voltage typically in the radio frequency (RF) range may be applied between the conductive top portion of the processing chamber, such as faceplate 2017, and showerhead 2025 and/or ion suppressor 2023 to ignite a plasma in chamber plasma region 2015 during deposition. An RF power supply may generate a high RF frequency of 13.56 MHz but may also generate other frequencies alone or in combination with the 13.56 MHz frequency.

Plasma power can be of a variety of frequencies or a combination of multiple frequencies. In the exemplary processing system the plasma may be provided by RF power delivered to faceplate 2017 relative to ion suppressor 2023 and/or showerhead 2025. The RF power may be between about 10 watts and about 2000 watts, between about 100 watts and about 2000 watts, between about 200 watts and about 1500 watts, or between about 200 watts and about 1000 watts in different embodiments. The RF frequency applied in the exemplary processing system may be low RF frequencies less than about 200 kHz, high RF frequencies between about 10 MHz and about 15 MHz, or microwave frequencies greater than or about 1 GHz in different embodiments. The plasma power may be capacitively-coupled (CCP) or inductively-coupled (ICP) into the remote plasma region.

The top plasma region 2015 may be left at low or no power when a bottom plasma in the substrate processing region 2033 is turned on to, for example, cure a film or clean the interior surfaces bordering substrate processing region 2033. A plasma in substrate processing region 2033 may be ignited by applying an AC voltage between showerhead 2055 and the pedestal 2065 or bottom of the chamber. A cleaning gas may be introduced into substrate processing region 2033 while the plasma is present.

A fluid, such as a precursor, for example a fluorine-containing precursor, may be flowed into the processing region 2033 by embodiments of the showerhead described herein. Excited species derived from the process gas in the plasma region 2015 may travel through apertures in the ion suppressor 2023, and/or showerhead 2025 and react with an additional precursor flowing into the processing region 2033 from a separate portion of the showerhead. Alternatively, if all precursor species are being excited in plasma region 2015, no additional precursors may be flowed through the separate portion of the showerhead. Little or no plasma may be present in the processing region 2033 according to embodiments. Excited derivatives of the precursors may combine in the region above the substrate and, on occasion, on the substrate to etch structures or remove species on the substrate in disclosed applications.

Exciting the fluids in the first plasma region 2015 directly, or exciting the fluids in the RPS unit 2001, may provide several benefits. The concentration of the excited species derived from the fluids may be increased within the processing region 2033 due to the plasma in the first plasma region 2015. This increase may result from the location of the plasma in the first plasma region 2015. The processing region 2033 may be located closer to the first plasma region 2015 than the remote plasma system (RPS) 2001, leaving less time for the excited species to leave excited states through collisions with other gas molecules, walls of the chamber, and surfaces of the showerhead.

The uniformity of the concentration of the excited species derived from the process gas may also be increased within the processing region 2033. This may result from the shape of the first plasma region 2015, which may be more similar to the shape of the processing region 2033. Excited species created in the RPS unit 2001 may travel greater distances in order to pass through apertures near the edges of the showerhead 2025 relative to species that pass through apertures near the center of the showerhead 2025. The greater distance may result in a reduced excitation of the excited species and, for example, may result in a slower growth rate near the edge of a substrate. Exciting the fluids in the first plasma region 2015 may mitigate this variation for the fluid flowed through RPS 2001.

The processing gases may be excited in the RPS unit 2001 and may be passed through the showerhead 2025 to the processing region 2033 in the excited state. Alternatively, power may be applied to the first processing region to either excite a plasma gas or enhance an already excited process gas from the RPS. While a plasma may be generated in the processing region 2033, a plasma may alternatively not be generated in the processing region. In one example, the only excitation of the processing gas or precursors may be from exciting the processing gases in the RPS unit 2001 to react with the substrate 2055 in the processing region 2033.

In addition to the fluid precursors, there may be other gases introduced at varied times for varied purposes, including carrier gases to aid delivery. A treatment gas may be introduced to remove unwanted species from the chamber walls, the substrate, the deposited film and/or the film during deposition. A treatment gas may be excited in a plasma and then used to reduce or remove residual content inside the chamber. In other disclosed embodiments the treatment gas may be used without a plasma. When the treatment gas includes water vapor, the delivery may be achieved using a mass flow meter (MFM), mass flow controller (MFC), an injection valve, or by commercially available water vapor generators. The treatment gas may be introduced to the processing region 2033, either through the RPS unit or bypassing the RPS units, and may further be excited in the first plasma region.

FIG. 5B shows a detailed view of the features affecting the processing gas distribution through faceplate 2017. As shown in FIGS. 5A and 5B, faceplate 2017, cooling plate 2003, and gas inlet assembly 2005 intersect to define a gas supply region 2058 into which process gases may be delivered from gas inlet 2005. The gases may fill the gas supply region 2058 and flow to first plasma region 2015 through apertures 2059 in faceplate 2017. The apertures 2059 may be configured to direct flow in a substantially unidirectional manner such that process gases may flow into processing region 2033, but may be partially or fully prevented from backflow into the gas supply region 2058 after traversing the faceplate 2017.

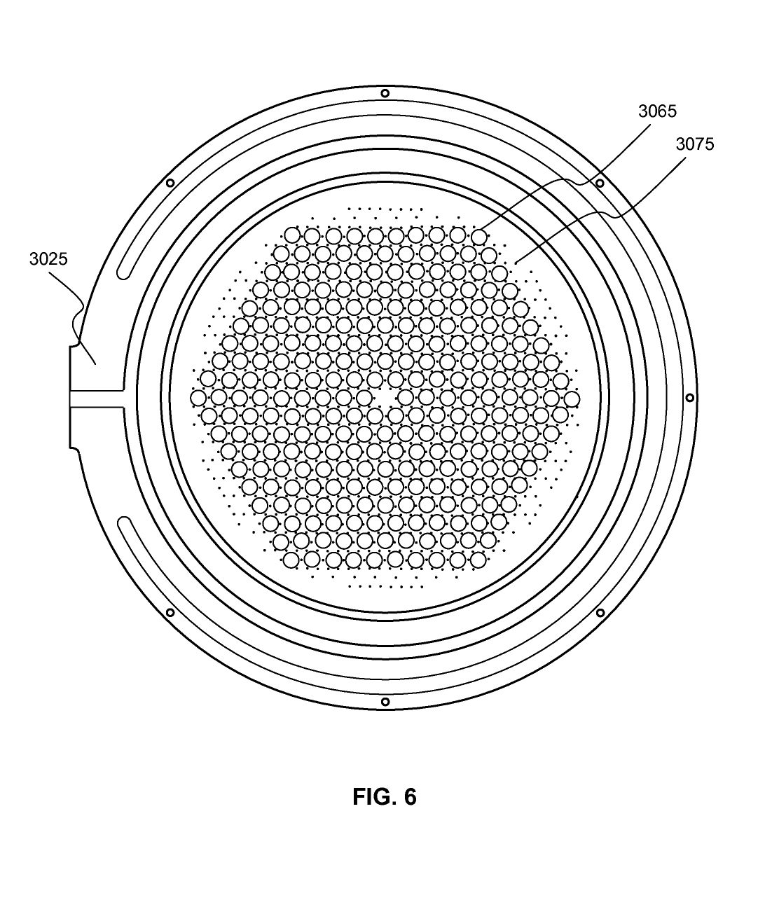

The gas distribution assemblies such as showerhead 2025 for use in the processing chamber section 2000 may be referred to as dual channel showerheads (DCSH) and are additionally detailed in the embodiments described in FIGS. 5A-5B as well as FIG. 6 herein. The dual channel showerhead may provide for etching processes that allow for separation of etchants outside of the processing region 2033 to provide limited interaction with chamber components and each other prior to being delivered into the processing region.

The showerhead 2025 may comprise an upper plate 2014 and a lower plate 2016. The plates may be coupled with one another to define a volume 2018 between the plates. The coupling of the plates may be so as to provide first fluid channels 2019 through the upper and lower plates, and second fluid channels 2021 through the lower plate 2016. The formed channels may be configured to provide fluid access from the volume 2018 through the lower plate 2016 via second fluid channels 2021 alone, and the first fluid channels 2019 may be fluidly isolated from the volume 2018 between the plates and the second fluid channels 2021. The volume 2018 may be fluidly accessible through a side of the gas distribution assembly 2025. Although the exemplary system of FIG. 5A includes a dual-channel showerhead, it is understood that alternative distribution assemblies may be utilized that maintain first and second precursors fluidly isolated prior to the processing region 2033. For example, a perforated plate and tubes underneath the plate may be utilized, although other configurations may operate with reduced efficiency or not provide as uniform processing as the dual-channel showerhead as described.

In the embodiment shown, showerhead 2025 may distribute via first fluid channels 2019 process gases which contain plasma effluents upon excitation by a plasma in chamber plasma region 2015 or from RPS unit 2001. In embodiments, the process gas introduced into the RPS unit 2001 and/or chamber plasma region 2015 may contain fluorine, e.g., CF₄, NF₃, or XeF₂, oxygen, e.g. N₂O, or hydrogen-containing precursors, e.g. H₂ or NH₃. One or both process gases may also include a carrier gas such as helium, argon, nitrogen (N₂), etc. Plasma effluents may include ionized or neutral derivatives of the process gas and may also be referred to herein as a radical-fluorine precursor, referring to the atomic constituent of the process gas introduced. In an example, a fluorine-containing gas, such as NF₃, may be excited in the RPS unit 2001 and passed through regions 2015 and 2033 without the additional generation of plasmas in those regions. Plasma effluents from the RPS unit 2001 may pass through the showerhead 2025 and then react with the substrate 2055. After passing through the showerhead 2025, plasma effluents may include radical species and may be essentially devoid of ionic species or UV light. These plasma effluents may react with films on the substrate 2055, e.g., titanium nitride and other masking material.

The gas distribution assemblies 2025 for use in the processing chamber section 2000 are referred to as dual channel showerheads (DCSH) and are detailed in the embodiments described in FIG. 6 herein. The dual channel showerhead may allow for flowable deposition of a material, and separation of precursor and processing fluids during operation. The showerhead may alternatively be utilized for etching processes that allow for separation of etchants outside of the reaction zone to provide limited interaction with chamber components and each other prior to being delivered into the processing region.

FIG. 6 is a bottom view of a showerhead 3025 for use with a processing chamber according to disclosed embodiments. Showerhead 3025 may correspond with the showerhead shown in FIG. 5A. Through-holes 3065, which show a view of first fluid channels 2019, may have a plurality of shapes and configurations in order to control and affect the flow of precursors through the showerhead 3025. Small holes 3075, which show a view of second fluid channels 2021, may be distributed substantially evenly over the surface of the showerhead, even among the through-holes 3065, which may help to provide more even mixing of the precursors as they exit the showerhead than other configurations.

As used herein “substrate” may be a support substrate with or without layers formed thereon. A patterned substrate may be an insulator or a semiconductor of a variety of doping concentrations and profiles and may, for example, be a semiconductor substrate of the type used in the manufacture of integrated circuits. Exposed “silicon” of the patterned substrate is predominantly Si but may include minority concentrations of other elemental constituents such as nitrogen, oxygen, hydrogen and carbon. In embodiments, silicon consists of or essentially of silicon. Exposed “silicon nitride” of the patterned substrate is predominantly Si₃N₄ but may include minority concentrations of other elemental constituents such as oxygen, hydrogen and carbon. In embodiments, silicon nitride consists of or essentially of silicon and nitrogen. Exposed “silicon oxide” of the patterned substrate is predominantly SiO₂ but may include minority concentrations of other elemental constituents such as nitrogen, hydrogen and carbon. In embodiments, silicon oxide consists of or essentially of silicon and oxygen.

The term “precursor” is used to refer to any process gas which takes part in a reaction to either remove material from or deposit material onto a surface. “Plasma effluents” describe gas exiting from the remote plasma region (e.g. the chamber plasma region) and entering the substrate processing region. Plasma effluents are in an “excited state” wherein at least some of the gas molecules are in vibrationally-excited, dissociated and/or ionized states. A “radical precursor” is used to describe plasma effluents (a gas in an excited state which is exiting a plasma) which participate in a reaction to either remove material from or deposit material on a surface. “Radical-fluorine” is a radical precursor which contain fluorine but may contain other elemental constituents. The phrase “inert gas” refers to any gas which does not form chemical bonds in the film during or after the etch process. Exemplary inert gases include noble gases but may include other gases so long as no chemical bonds are formed when (typically) trace amounts are trapped in a film.

The terms “gap” and “trench” are used throughout with no implication that the etched geometry has a large horizontal aspect ratio. Viewed from above the surface, trenches may appear circular, oval, polygonal, rectangular, or a variety of other shapes. A trench may be in the shape of a moat around an island of material. The term “via” is used to refer to a low aspect ratio trench (as viewed from above) which may or may not be filled with metal to form a vertical electrical connection. As used herein, a conformal etch process refers to a generally uniform removal of material on a surface in the same shape as the surface, i.e., the surface of the etched layer and the pre-etch surface are generally parallel. A person having ordinary skill in the art will recognize that the etched interface likely cannot be 100% conformal and thus the term “generally” allows for acceptable tolerances.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a trench” includes a plurality of such trenches, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A method of etching a patterned substrate, the method comprising:
transferring the patterned substrate into a substrate processing region of a substrate processing chamber, wherein the patterned substrate has an exposed portion of silicon nitride and an exposed portion of silicon;
flowing a fluorine-containing precursor into a remote plasma region fluidly coupled to the substrate processing region while forming a remote plasma in the remote plasma region to produce plasma effluents;
flowing a hydrogen-containing precursor into the substrate processing region without first passing the hydrogen-containing precursor through the remote plasma region;
combining the hydrogen-containing precursor and the plasma effluents in the substrate processing region, and etching the exposed portion of silicon nitride.

2. The method of claim 1 wherein the exposed portion of silicon nitride consists essentially of silicon and nitrogen and the exposed portion of silicon consists of silicon.

3. The method of claim 1 wherein the hydrogen-containing precursor comprises one of hydrogen, water or an alcohol.

4. The method of claim 1 wherein the hydrogen-containing precursor is not excited in any plasma prior to entering the substrate processing region.

5. The method of claim 1 further comprising flowing an oxygen-containing precursor into the remote plasma region during the operation of flowing the fluorine-containing precursor.

6. A method of etching a patterned substrate, the method comprising:
transferring the patterned substrate into a substrate processing region of a substrate processing chamber, wherein the patterned substrate has exposed silicon nitride and exposed silicon;
flowing a fluorine-containing precursor into a remote plasma region fluidly coupled to the substrate processing region while forming a remote plasma in the remote plasma region to produce plasma effluents;
flowing water vapor into the substrate processing region without first passing the water vapor through any remote plasma; and
etching the exposed silicon nitride.

7. The method of claim 6 wherein a selectivity of the operation (exposed silicon nitride:exposed silicon) is greater than or about 50:1.

8. The method of claim 6 wherein the operation of forming the remote plasma comprises a remote plasma power between 25 W and 500 W.

9. The method of claim 6 wherein a pressure in the substrate processing region is between about 0.1 Torr and about 15 Torr during the operation of etching the exposed silicon nitride.

10. The method of claim 6 wherein an electron temperature in the substrate processing region is less than 0.5 eV during the operation of etching the exposed silicon nitride.

11. The method of claim 6 wherein plasma effluents pass through an ion suppressor disposed between the remote plasma region and the substrate processing region.

12. The method of claim 6 wherein the fluorine-containing precursor comprises NF₃.

13. The method of claim 6 wherein the fluorine-containing precursor comprises a precursor selected from the group consisting of hydrogen fluoride, atomic fluorine, diatomic fluorine, carbon tetrafluoride and xenon difluoride.

14. The method of claim 6 wherein a temperature of the patterned substrate is between about 25° C. and about 90° C. during the operation of etching the exposed silicon nitride.

15. A method of etching a patterned substrate, the method comprising:
transferring the patterned substrate into a substrate processing region of a substrate processing chamber, wherein the patterned substrate has exposed silicon nitride and exposed silicon;
flowing nitrogen trifluoride into a remote plasma region fluidly coupled to the substrate processing region while forming a remote plasma in the remote plasma region to produce plasma effluents;
flowing water vapor into the substrate processing region without first passing the water vapor through the remote plasma region;
etching the exposed silicon nitride, wherein a temperature of the patterned substrate is between about 40° C. and about 80° C. during the operation of etching the exposed silicon nitride; and
removing the patterned substrate from the substrate processing region.
